(19) United States
(12) Patent Application Publication
(10) Pub. No.: US 2010/0117186 A1
(43) Pub. Date: May 13, 2010

(54) Semiconductor device and method of producing the same

(76) Inventors: Hiroshi Kambayashi, Tokyo (JP); Shusuke Kaya, Tokyo (JP); Nariaki Ikeda, Tokyo (JP)

Correspondence Address: Kubotera & Associates, LLC, 200 Daingerfield Rd, Suite 202, Alexandria, VA, 22314, US

(21) Appl. No.: 12/457,904

(22) Filed: Jun. 24, 2009

(30) Foreign Application Priority Data
Nov. 11, 2008 (JP) 2008-168224

(51) Int. Cl. H01L 29/47; H01L 21/28; H01L 21/82

(52) U.S. Cl. 257/473; 438/606; 257/E29.149; 257/E21.186; 257/E21.602

(57) ABSTRACT

The invention provides a semiconductor device and a method for fabricating the same capable of preventing a field plate portion from being delaminated from an insulating film by stress inherent in a semiconductor layer even if the stress is released in forming a trench in part of the semiconductor layer where the semiconductor device is to be separated and capable of having a higher breakdown property of the semiconductor device. The semiconductor device has source, drain and gate electrodes, insulating films that insulate the electrodes on an electron supplying layer and a mesa-structure formed at part where the semiconductor device is to be separated. The gate electrode has a first electrode layer having a function of the electrode and a second electrode layer having a field plate portion whose part that contacts with the insulating film is made of a metallic material that adheres well to the insulating film.

### CROSS REFERENCE TO RELATED APPLICATIONS

This application claims priority from a Japanese application No. 2008-168224 filed on Jun. 27, 2008. The entire content of which is incorporated herein by reference.

### BACKGROUND OF THE INVENTION

The present invention relates to a semiconductor device such as a GaN hetero-junction field effect transistor, and a method of producing the semiconductor device.

A nitride semiconductor such as GaN, AlGaN, and the likes has a wide energy band gap as compared to a conventional semiconductor such as Si and GaAs, and has been an excellent semiconductor for a high-temperature operation and a high breakdown voltage device. As opposed to a wide band gap semiconductor such as SiC, the nitride semiconductors (a GaN semiconductor) can specifically form a hetero-junction structure such as AlGaN/GaN. Accordingly, a nitride semiconductor hetero-junction FET (HFET) has been actively developed (refer to Patent References 1 and 2)

A semiconductor device formed of a compound semiconductor has been required to have an improved breakdown voltage. To this end, an FET such as an HFET has been required to have an improved gate breakdown voltage. In order to improve the gate breakdown voltage, it is necessary to reduce a convergence of an electric field at an edge of a gate electrode. It is known that a field plate structure is effective to reduce the convergence of the electric field (refer to Patent Reference 3)
Patent Reference 1: Japanese Patent Publication No. 2005-129856
Patent Reference 2: Japanese Patent Publication No 2003-179082
Patent Reference 3: Japanese Patent Publication No. 2005-093864

Patent Reference 3 has disclosed a semiconductor device having the field plate structure described above. In the semiconductor device, a plurality of electrodes is disposed on a semiconductor layer with an insulating film in between. One of the electrodes disposed has a schottky electrode layer having a schottky-junction with the semiconductor layer and a field plate electrode layer deposited on the schottky electrode layer. The field plate electrode layer extends over the insulating film, and has an extended portion tightly contacting with the insulating film. With the semiconductor device, it is possible to prevent the extended portion of the field plate electrode layer from being delaminated from the insulating film, thereby improving a breakdown voltage.

In the semiconductor device such as the GaN FET having the field plate structure described above, the semiconductor layer around the semiconductor device may be removed to form a trench, so that the trench is cut through dicing in order to reduce damage on the semiconductor device when the semiconductor device is cut through dicing.

In a case of the AlGaN/GaN HFET using a Si substrate, a gate electrode may be formed of a laminate structure (Ni/Au) of Ni having a high schottky barrier with respect to an electron supplying layer made of AlGaN and Au for reducing a metallic resistance of the electrode. A passivation film (insulating film) on the electron supplying layer made of AlGaN may be formed of SiO₂.

In the semiconductor device described above, a stress is inherently generated in the semiconductor layer made of GaN and the like epitaxially grown on the Si substrate due to a difference in a lattice constant with that of Si. When the trench is formed in the semiconductor layer around the semiconductor device through etching, the stress is released. When the semiconductor device such as the AlGaN/GaN HFET is formed in the field plate structure described above, and the field plate portion of the gate electrode is formed of Ni and the like, the field plate portion tends to be delaminated from the insulating film due to the released stress described above and inferior adhesiveness between Ni and SiO₂.

In view of the problems described above, an object of the present invention is to provide a semiconductor device with an improved breakdown voltage and a method of producing the semiconductor device. In the semiconductor device, it is possible to prevent a field plate portion from being delaminated from an insulating film when a stress inherently generated in a semiconductor layer is released upon forming a trench in the semiconductor layer where the semiconductor device is cut.

### SUMMARY OF THE INVENTION

In order to attain the objects described above, according to a first aspect of the invention, a semiconductor device includes a semiconductor layer formed on a substrate and made of a compound semiconductor; an insulating film formed on a part of the semiconductor layer and having an aperture; a plurality of electrodes formed on the semiconductor layer; and a mesa-structure formed at a portion of the semiconductor layer to be separated into elements. Further, one of the electrodes includes a first electrode layer formed in the aperture and having a function of a schottky electrode and a second electrode layer formed on the first electrode layer and having a field plate portion. The field plate portion extends toward another of the electrodes on the insulating film and has a contact portion contacting with the insulating film and formed of a metallic material attached to the insulating film.

In the first aspect of the present invention, one of the electrodes includes the second electrode layer formed on the first electrode layer and having the field plate portion. Further, the field plate portion has the contact portion contacting with the insulating film and formed of the metallic material attached to the insulating film. Therefore, even when a stress generated within the semiconductor layer is released in forming a trench at the portion of the semiconductor layer to be separated into elements through etching, it is possible to prevent the field plate from being delaminated from the insulating film due to the stress, thereby improving a breakdown voltage. Further, the trench is formed at the portion of the semiconductor layer to be separated into elements. Accordingly, it is possible to reduce damage on the semiconductor device when the semiconductor device is cut with a dicer.

According to a second aspect of the invention, the mesa-structure has a trench having a depth reaching the substrate. With the structure, it is possible to separate the semiconductor device into the elements simply through inserting a dicer into the trench in the mesa-structure, thereby further reducing damage on the semiconductor device.

According to a third aspect of the invention, the first electrode layer has a laminate structure formed of Au and at least one of Ni, Pd, Ir and Pt, and the second electrode layer has a layer made of Ti or Cr on a side of the contact portion.

According to a fourth aspect of the invention, the second electrode layer has a laminated structure formed of Ti, Pt and Au, or Cr, Pt and Au sequentially laminated from a side of the contact portion contacting with an end portion of the first electrode layer.

According to a fourth aspect of the invention, the compound semiconductor is a nitride semiconductor.

According to a sixth aspect of the invention, a method of producing a semiconductor device including steps of the steps of: forming a semiconductor layer made of a compound semiconductor on a substrate; forming a plurality of electrodes electrically insulated with an insulating film on the semiconductor layer; and forming a trench at a portion of the semiconductor layer to be separated into elements. Further, one of the electrodes includes a first electrode layer formed in the aperture and having a function of a schottky electrode and a second electrode layer formed on the first electrode layer and having a field plate portion. The field plate portion extends toward another of the electrodes on the insulating film and has a contact portion contacting with the insulating film and formed of a metallic material attached to the insulating film

### BRIEF DESCRIPTION OF THE DRAWINGS

FIG. 1 is a section view showing a schematic structure of a HFET according an embodiment of the invention; and

FIG. 2 is an enlarged partial section view of a gate electrode part of the HFET shown in FIG. 1.

### DETAILED DESCRIPTION OF PREFERRED EMBODIMENTS

Embodiments of the invention will be explained below with reference to the drawings.

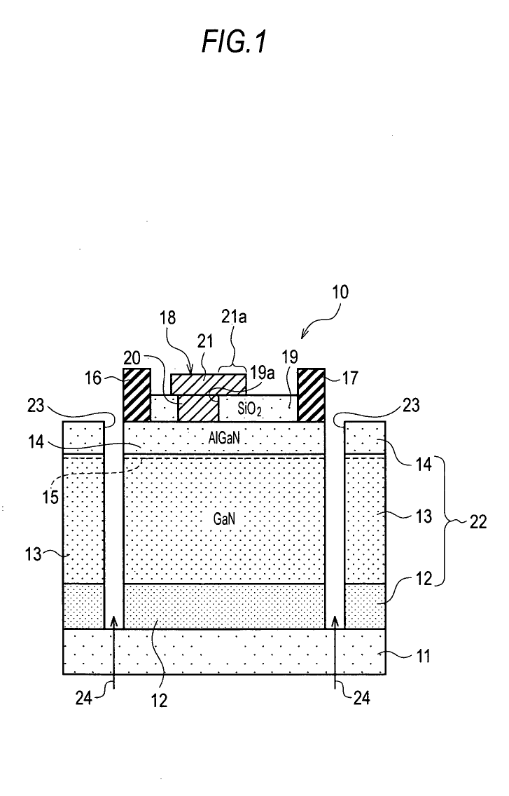

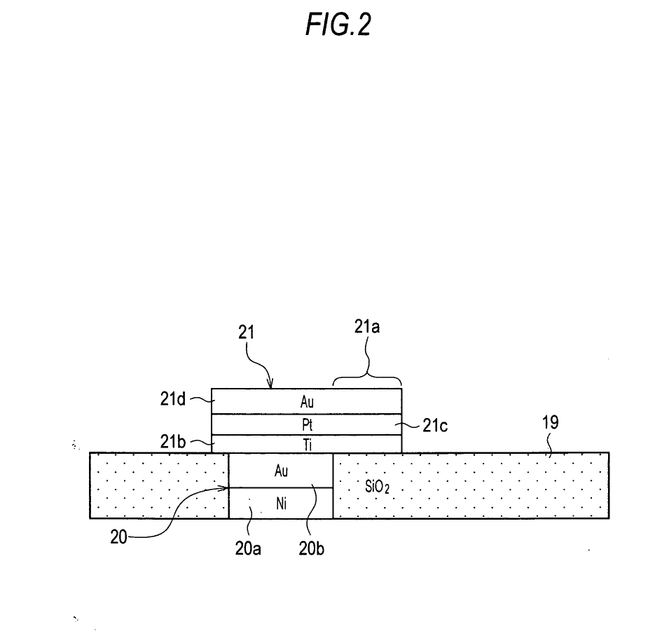

FIG. 1 is a section view showing a schematic structure of an AlGaN/GaN Hetero-junction FET (HFET) 10 as a semiconductor device according to an embodiment of the invention. FIG. 2 is an enlarged partial section view of a gate electrode part of the HFET 10 shown in FIG. 1.

As shown in FIG. 1, the HFET 10 has a semiconductor layer 22 formed of a laminated structure of a buffer layer 12 made of AlGaN, an electron traveling layer 13 made of GaN and an electron supplying layer 14 made of Al_{0.25}Ga_{0.75}N that is thinner than the electron traveling layer 13 in this order on a silicon (Si) substrate 11. In the HFET 10, a hetero-junction interface is formed of the electron supplying layer 14 made of AlGaN having a wide band gap and the electron traveling layer 13 made of GaN having a band gap narrower than that of AlGaN.

A high-concentrate two-dimensional electron gas layer 15 is formed at the AlGaN/GaN hetero-junction interface through spontaneous polarization and a piezoelectric effect for reducing a resistance of a channel, i.e., on-state resistance of the HFET 10.

The HFET 10 has a plurality of electrodes such as a source electrode 16, a drain electrode 17, and a gate electrode 18, and insulating film layers 19 made of SiO₂ or the like formed on the electron supplying layer 14. The insulating film layers 19 are formed between the source electrode 16 and the gate electrode 18, and between the gate electrode 18 and the drain electrode 17 on the electron supplying layer 14, respectively. Accordingly, electrical insulation is made between the source electrode 16 and the gate electrode 18 and between the gate electrode 18 and the drain electrode 17, respectively. It is noted that a contact layer (not shown) is formed between the electron supplying layer 14 and the source electrode 16 or the drain electrode 17 for reducing a contact resistance between the respective layers. The contact layer is formed of a nitride compound semiconductor with n-type impurities heavily doped.

In the embodiment, the HFET 10 has a mesa-structure 23 formed at a part of a semiconductor layer 22 where the semiconductor device is to be separated. The mesa-structure 23 is a deep mesa having a trench etched deeply so as to reach the silicon substrate 11.

The gate electrode 18, i.e., one of the electrodes, has a first electrode layer 20 functioning as a schottky electrode and a second electrode layer 21 layered on the first electrode layer 20. The second electrode layer 21 has a field plate portion 21a that extends to a side of the drain electrode 17 and has a part that contacts with the insulating film layer 19 made of a metallic material that contact tightly to the insulating film layer 19.

As shown in FIGS. 1 and 2, the first electrode layer 20 of the gate electrode 18 is formed in an aperture 19a of the insulating film layer 19 and has a laminated structure of a first layer 20a that is a metallic material having a schottky-junction with the semiconductor layer 22 and a second layer 20b that is a metallic material that reduces a metallic resistance. A material of the first layer 20a is selected from either one of Ni, Pd, Ir and Pt. According to the present embodiment, the first electrode layer 20 has a laminated structure of the first layer 20a made of Ni and the second layer 20b made of Au, i.e., the laminate structure of Ni/Au.

In the embodiment, as shown in FIGS. 1 and 2, the second electrode layer 21 of the gate electrode 18 has a first layer 21b made of a metallic material that adheres well to the insulating film layer 19; a second layer 21c; and a third layer 21d made of a metallic material that reduces the metallic resistance in order from the side contacting with the second layer 20b of the first electrode layer 20 and the insulating film layer 19. Ti or Cr is used for the first layer 21b, and Ti is used for the first layer 21b.

It is necessary to treat the first electrode layer 20 having the laminated structure of Ni/Au by heat at around 400° C. to 600° C. in order to obtain fine schottky characteristics. Therefore, the second layer 21c is formed of a metallic material, e.g., Pt, as a barrier for preventing Au of the third layer 21d from diffusing to Ti of the first layer 21b in applying the heat treatment. Thus, the laminated structure of Ti, Pt and Au is used for the second electrode layer 21 of the gate electrode 18. It is noted that the first and second electrode layers 20 and 21 are electrically connected at junction interfaces thereof.

In the HFET 10 having the structure as described above, when the source and drain electrodes 16 and 17 are activated, electrons supplied to the electron traveling layer 13 travel quickly within the two-dimensional electron gas layer 15 and move to the drain electrode 17. At this time, it is possible to control the electrons moving from the source electrode 16 to the drain electrode 17, i.e., a drain current, by controlling voltage applied to the gate electrode 18 to vary a thickness of a depletion layer right under the gate electrode 18.

Ti, Cr or the like used as the adhesive material for the second electrode layer 21 as described above has high adhesiveness to the insulating film layer 19 as compared to Ni, Pd, Ir, Pt and others used as the schottky-junction materials. Accordingly, the field plate portion 21a adheres well to the insulating film layer 19 in the HFET10, thereby improving high breakdown property of the HEFT 10.

Next, a method of producing the HFET 10 will be explained. At first, trimethyl gallium (TMGa), trimethyl aluminum (TMAl) and ammonium (NH₃) as base materials of the nitride compound semiconductor are introduced into a MOCVD (Metal Organic Chemical Vapor Deposition) apparatus in which the silicon substrate 11 is installed at a vacuum level of 10 hPa and flow rates of 10 cm³/min, 50 cm³/min and 121 cm³/min, respectively. Accordingly, the buffer layer 12 made of AlGaN and having a thickness of 50 nm is formed on the silicon substrate 11 at a growth temperature of 110° C.

Next, TMGa and NH₃ are introduced at flow rates of 10 cm³/min and 121 cm³/min, respectively, to form the electron traveling layer 13 made of GaN and having a thickness of 40 nm on the buffer layer 12 at a growth temperature of 1,050° C.

Next, TMAl, TMGa and NH₃ are introduced at flow rates of 50 cm³/min, 10 cm³/min and 121 cm³/min, respectively, to form the electron supplying layer 14 made of un-doped Al_{0.25}Ga_{0.75}N and having a thickness of 30 nm on the electron traveling layer 13 at a growth temperature of 1,050° C. Carrier concentration of the electron supplying layer 14 is 1×10¹⁶/cm³.

Next, a mask made of a SiO₂ film is formed on the electron supplying layer 14 through patterning utilizing photolithography, and apertures corresponding to the source and drain electrodes 16 and 17 are formed at regions where the electrodes are to be formed. Then, Ti, Al and Au, for example, are evaporated in the apertures one after another with thicknesses of 50 nm, 50 nm and 10 nm to form the source and drain electrodes 16 and 17.

Next, after the mask on the electron supplying layer 14 is removed, the SiO₂ film as the insulating film layer 19 is deposited on the electron supplying layer 14 between the source and drain electrodes 16 and 17. Then, a region of the insulating film layer 19 where the gate electrode 18 is to be formed is etched, so that the aperture corresponding to a shape of the first electrode layer 20 is formed. Ni and Au are deposited in the aperture one after another with thicknesses of 10 nm and 200 nm, respectively, to form the first electrode layer 20. It is possible to deposit one of Pt, Pd and Ir, for example, instead of Ni.

Next, a mask made of a photo-resist is formed on the electron supplying layer 14, the source electrode 16, the drain electrode 17, the first electrode layer 20, and the insulating film layer 19. Then, a region of the mask where the second electrode layer 21 is to be formed is etched, so that the aperture corresponding to a shape of the second electrode layer 21 is formed. Then, Ti, Pt and Au are deposited one after another in the aperture with thicknesses of 50 nm, 200 nm and 200 nm, respectively, to form the second electrode layer 21. After that, the mask made of the photo-resist is removed.

Finally, a SiO₂ film is formed on the electron supplying layer 14, the source electrode 16, the drain electrode 17, the second electrode layer 21, and the insulating film layer 19. Then, patterning the SiO₂ film is patterned to open a part where the trench of the mesa-structure 23 is to be formed. In the opening, the semiconductor layer 22 is etched and removed from a surface to a depth reaching the silicon substrate 11 to form the mesa-structure 23 with a substantially perpendicular wall surface. Thereby, the HFET 10 shown in FIG. 1 is completed. It is noted that a reference numeral (24) shown in FIG. 1 is a cut line of a dicer.

In the embodiment, it is possible to reduce the convergence of electric field at the end of the gate electrode 18 by the gate electrode 18 having the field plate structure formed by laminating the first and second electrode layers 20 and 21. Further, the second electrode layer 21 of the gate electrode 18 that contacts with the insulating film layer 19 made of SiO₂ has the field plate portion 21a made of the metallic material that adheres well to the insulating film layer 19. Therefore, even if the stress inherent in the semiconductor layer 22 is released in forming the trench of the mesa-structure 23 at the part of the semiconductor layer 22 where the semiconductor device is to be separated, it is possible to prevent the field plate portion 21a of the gate electrode 18 from being removed by the stress. Accordingly, it is possible to get the high breakdown property of the semiconductor device (HEFH 10).

Still more, because the first electrode layer 20 has the laminated structure of the first layer 20a made of Ni and the second layer 20b made of Au (laminate structure of Ni/Au), Ni/Au having a high barrier from the electron supplying layer 14 made of AlGaN presents an excellent schottky characteristic. Accordingly, the gate electrode has a high barrier, so that it is possible to reduce a gate leak current and prevent delaminating of the field plate portion 21a. An off-state breakdown property also improves by reducing the gate leak current.

Because the trench of the mesa-structure 23 is formed at the part of the semiconductor layer 22 to be cut by the dicer (where the device is to be separated by dicing), the semiconductor device itself receives less damages when the device is cut by the dicer.

While the present embodiment is explained with the HFET as an example, the invention is applicable also to various FETs such as MISFET (Metal Insulating film Semiconductor FET), MOSFET (Metal Oxide Semiconductor FET) and MESFET (Metal Semiconductor FET).

In the embodiment, the HFET 10 has the deep mesa-structure 23 having the trench etched to the depth reaching the silicon substrate 11. The invention is applicable also to a semiconductor device in which a mesa-structure having a trench having a different shape, a different depth, a different number of trenches from the mesa-structure 23 is formed.

In the embodiment, the silicon substrate 11 is provided, and the invention is applicable to semiconductor devices using not only the silicon substrate but also other substrates.

The invention is applicable also to various diodes such as a schottky diode other than the FET. For instance, the invention is applicable also to a schottky diode having cathode and anode electrodes formed on a semiconductor layer, electrically insulated from each other by an insulating film and provided with a field plate structure in the anode electrode that schottky-junctions with the semiconductor layer. That is, in the schottky diode to which the invention is applied, the anode electrode has a first electrode layer having a function of a schottky electrode and a second electrode layer layered on the first electrode layer and having a field plate portion that extends to the side of the cathode electrode on the insulating film and whose part that contacts with the insulating film is made of a metallic material that adheres well to the insulating film similarly to the gate electrode 18 described above.

According to the invention, the second electrode layer of one electrode of the plurality of electrodes has the field plate portion that is made of the metallic material that contacts well with the insulating film as described above. Therefore, even if the stress inherent within the semiconductor layer is released in forming the trench by means of etching at the part of the semiconductor layer where the semiconductor device is to be separated, it is possible to prevent the field plate from being delaminated by the stress. Thus, it becomes possible to enhance the breakdown voltage of the semiconductor.

Although the invention has been described by way of the exemplary embodiments, it should be understood that those skilled in the art might make many changes and substitutions without departing from the spirit and scope of the invention. It is obvious from the definition of the appended claims that the embodiments with such modifications also belong to the scope of the invention.

What is claim is:

1. A semiconductor device, comprising:
a semiconductor layer formed on a substrate and made of a compound semiconductor;
an insulating film formed on a part of the semiconductor layer and having an aperture;
a plurality of electrodes formed on the semiconductor layer, one of said electrodes including a first electrode layer formed in the aperture and having a function of a schottky electrode and a second electrode layer formed on the first electrode layer and having a field plate portion, said field plate portion extending toward another of the electrodes on the insulating film and having a contact portion contacting with the insulating film and formed of a metallic material attached to the insulating film; and
a mesa-structure formed at a portion of the semiconductor layer to be separated into elements.

2. The semiconductor device according to claim 1, wherein said mesa-structure includes a trench having a depth reaching the substrate.

3. The semiconductor device according to claim 1, wherein said first electrode layer has a laminate structure formed of Au and at least one of Ni, Pd, Ir and Pt, and said second electrode layer has a layer made of Ti or Cr on a side of the contact portion.

4. The semiconductor device according to claim 1, wherein said second electrode layer has a laminated structure formed of Ti, Pt and Au, or Cr, Pt and Au sequentially laminated from a side of the contact portion contacting with an end portion of the first electrode layer.

5. The semiconductor device according to claim 1, wherein said compound semiconductor is a nitride semiconductor.

6. A method of producing a semiconductor device, comprising the steps of:
forming a semiconductor layer made of a compound semiconductor on a substrate;
forming a plurality of electrodes electrically insulated with an insulating film on the semiconductor layer, one of said electrodes including a first electrode layer formed in the aperture and having a function of a schottky electrode and a second electrode layer formed on the first electrode layer and having a field plate portion, said field plate portion extending toward another of the electrodes on the insulating film and having a contact portion contacting with the insulating film and formed of a metallic material attached to the insulating film; and
forming a trench at a portion of the semiconductor layer to be separated into elements.
